(19) United States
(12) Patent Application Publication
(10) Pub. No.: US 2009/0132876 A1
(43) Pub. Date: May 21, 2009

(54) Maintaining Error Statistics Concurrently Across Multiple Memory Ranks

(76) Inventors: Ronald Ernest Freking, Rochester, MN (US); Joseph Allen Kirscht, Rochester, MN (US); Elizabeth A. McGlone, Rochester, MN (US)

Correspondence Address: Robert R. Williams;IBM Corporation, Dept. 917, 3605 Highway 52 North, Rochester, MN, 55901-7829, US

(21) Appl. No.: 11/942,116

(22) Filed: Nov. 19, 2007

(51) Int. Cl. G11C 29/00

(52) U.S. Cl. 714/723

(57) ABSTRACT

A method and apparatus to maintain memory read error information concurrently across multiple ranks in a computer memory. An error detection unit associates a read error with a particular rank and with a particular chip in the rank. The error detection unit reports the error and the associated rank ID and chip ID to an error logging unit. The error logging unit maintains, for each rank ID and chip ID for which an error has been detected, a total number of errors that occur. A memory controller uses a fault pattern in the error logging unit to replace failing memory chips or memory ranks with a spare memory chip or a spare memory rank.

### FIELD OF THE INVENTION

This invention relates generally to memory controllers in computer systems. More particularly this invention relates to maintaining error statistics concurrently across multiple memory ranks.

### SUMMARY OF EMBODIMENTS OF THE INVENTION

Many modern computer systems comprise a memory and a memory controller. In memory, such as DRAMs (Dynamic Random Access Memory) or SRAMs (Static Random Access Memory) for examples, data stored in the memory may become corrupted, for example by one or more forms of radiation. Often this corruption presents itself as a “soft error”. For example, a single bit in a block of data read (such as a cache line that is read) may be read as a “0” whereas the single bit had been written as a “1”. Most modern computer systems use an error detection unit, most commonly an error checking and correcting (ECC) circuitry to correct a single bit error (SBE) before passing the block of data to a processor. The SBE may be a permanent “hard error” (a physical error in the memory or interconnection to the memory) or the SBE may be a “soft error”, as described above. Some modern computer systems are capable of correcting more than one error in the block of data read, requiring additional bits in the block of data read.

Some computer systems use “scrubbing” routines to correct soft errors. Scrubbing routines cycle through each rank in memory, reading from each chip in an instant rank, and writing data (corrected, if necessary, by the ECC circuitry) back into the each chip. Such computer systems maintain error statistics determined for each rank during scrubbing of the rank. The statistics can then be used to determine whether the rank has a “chip kill” (a nonfunctional chip), and, in some computer systems, a spare chip in the rank can be gated in to take the place of the nonfunctional chip. Such error statistics are only gathered during scrubbing in conventional systems. Since scrubbing in conventional systems goes rank by rank, a relatively long time (e.g., a day) may elapse before a hard error is detected in a rank scrubbed at the end of a scrubbing period. If such a hard error exists, ECC circuitry capable of correcting a SBE can not correct a soft error occurring, because the hard error plus the soft error would exceed the correction capability of the ECC circuitry. Similarly, if a first soft error occurs in a rank that is not scrubbed until the end of the scrubbing period, and a second soft error also occurs in the same rank, the ECC circuitry could not correct data read from that rank because two errors exist. Therefore, reliability of such a computer system is limited by how long the scrubbing period is.

In an embodiment of the invention, error statistics are maintained concurrently across multiple ranks in memory. Maintaining error statistics concurrently across multiple ranks in memory further includes accumulating error statistics during functional reads, as well as during scrubbing of the memory. Concurrently maintaining error statistics allows detecting of errors in memory chips or memory ranks more quickly than conventional rank by rank scrubbing of memory. In an embodiment, spare memory chips and/or spare memory ranks are gated in to replace memory ranks or memory chips found to have errors.

### BRIEF DESCRIPTION OF THE DRAWINGS

FIG. 1 is a block diagram of a computer system comprising a processor, a memory controller and a memory having a plurality of memory ranks.

FIG. 2 is a block diagram of a memory controller showing detail of wiring interconnects between chips in memory ranks and the memory controller.

FIG. 3 is a block diagram of an error logging unit.

FIG. 4 is a flowchart illustrating a method performed by the error logging unit.

FIG. 5 is a block diagram of the error logging unit with exemplary rank and chip ID information used to describe detection of a hard error for the same chip across multiple ranks.

FIG. 6 is a block diagram of a memory controller showing detail of wiring interconnects between chips in memory ranks and the memory controller, similar to FIG. 2, but having a spare memory chip in each rank of memory.

FIG. 7 is a high level flow chart illustrating a method embodiment of the invention.

FIG. 8 is a block diagram of an alternative embodiment of an error location list.

### DETAILED DESCRIPTION OF THE EMBODIMENTS

In the following detailed description of embodiments of the invention, reference is made to the accompanying drawings, which form a part hereof, and within which are shown by way of illustration specific embodiments by which the invention may be practiced. It is to be understood that other embodiments may be utilized and structural changes may be made without departing from the scope of the invention.

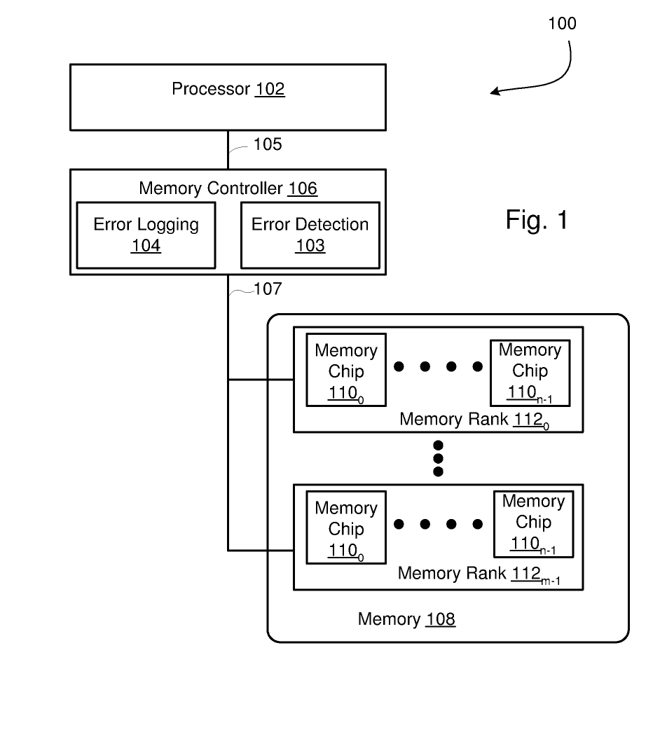

With reference now to the drawings, and, in particular, FIG. 1, computer system 100 is shown. Computer system 100 comprises one or more processor(s) 102, a processor bus 105 that couples processor 102 to a memory controller 106, and a memory 108 coupled to memory controller 106 by a memory bus 107. Memory 108 further comprises a plurality of memory ranks 112 (shown as memory ranks 112₀-112ₘ₋₁) of memory chips 110 (shown as memory chips 110₀-110ₙ₋₁). Memory chips 110 are typically DRAM (Dynamic Random Access Memory) chips.

A typical modern computer system 100 further includes many other components, such as networking facilities, disks and disk controllers, user interfaces, and the like, all of which are well known and discussion of which is not necessary for understanding of embodiments of the invention.

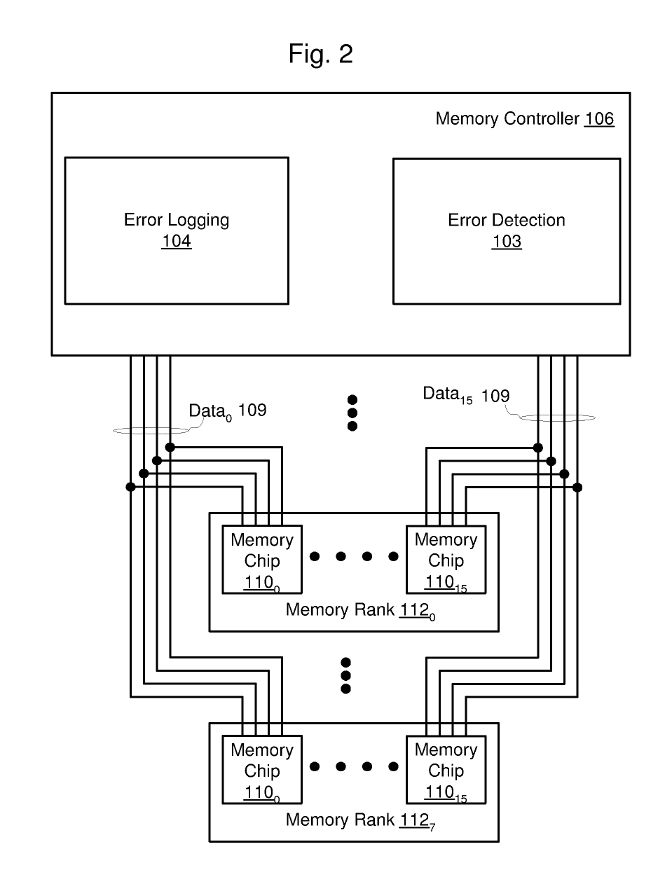

Turning now to FIG. 2, memory controller 106 is shown connected to eight memory ranks (memory ranks 112₀ through 112₇). Each memory rank further comprises sixteen memory chips (memory chips 110₀ through 110₁₅).

More or fewer memory ranks 112 are contemplated, as are more or fewer memory chips 110 on each rank. In particular, spare memory ranks 112 and spare memory chips 110 on each memory rank 112 are often included and are used to replace failing memory ranks 112 and/or failing memory chips 110. Some memory chips 110, or portions of some memory chips 110, may be used to store ECC bits.

As depicted, each memory chip 110 has four data connections, data 109, with which to receive and drive data. More or fewer data connections in a data 109 are contemplated, and four connections are used for exemplary purposes. For example, as shown, Data₀ 109 is coupled to memory chip 110₀ on each of memory ranks 112₀ to 112₇. Data₁₅ 109 is coupled to memory chips 110₁₅ on each of memory ranks 112₀ to 112₇. For simplicity, not all memory chips 110 in a rank, and not all memory ranks 112 are shown, and dots indicate omitted memory chips 110 and memory ranks 112. A fault on one or more bits on any data 109 is noted by error detection unit 103 in memory controller 106. While error detection unit 103 is described herein in terms of an error checking and correction (ECC) circuitry, in general, error detection unit 103 is an error detection unit capable of detecting errors in data read from memory chips 110. Other error detection units besides ECC may be used, for example, error detection unit 103 may be a simple parity checker. As mentioned before, an ECC implementation of error detection unit 103, depending on implementation, is capable of correcting a single bit error among all data 109 bits received, and can detect one or more additional failing bits. Other implementations can correct and detect additional bits.

While corresponding pins of multiple memory chips 110 are shown physically “dotted” in FIG. 2 as an instance of data 109, other configurations are possible. For example, a buffer chip on each memory rank 112 may physically isolate a memory chip 110 on a first memory rank 112 from a corresponding memory chip 110 on a second memory rank 112.

In addition, in an embodiment, memory controller 106, with suitable circuitry in memory ranks 112, performs a “wire test” to further test and diagnose failure(s) in interconnect (signaling conductors between chips and drivers/receivers on chips). Wire test is a commonly used technique to send one or more particular patterns from a first chip to a second chip and verify whether the patterns were or were not correctly received using software and/or hardware to do the verification. A particular implementation of wire test may be found, for example, in U.S. Pat. No. 6,711,706.

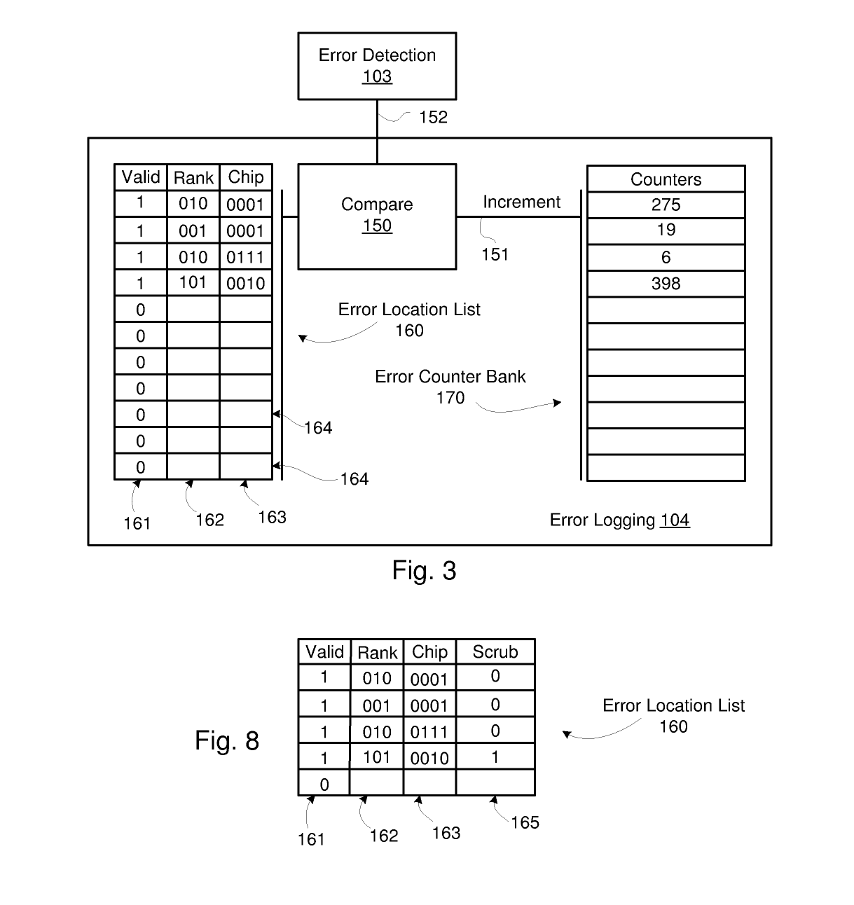

FIG. 3 illustrates error detection unit 103 and error logging unit 104, showing additional details of error logging unit 104. Error detection unit 103 is coupled to error logging unit 104 by error bus 152. Upon detection of an error in a data 109, error detection unit 103 transmits an error message via error bus 152 to error logging unit 104, the error message comprising rank and chip identification associated with the error.

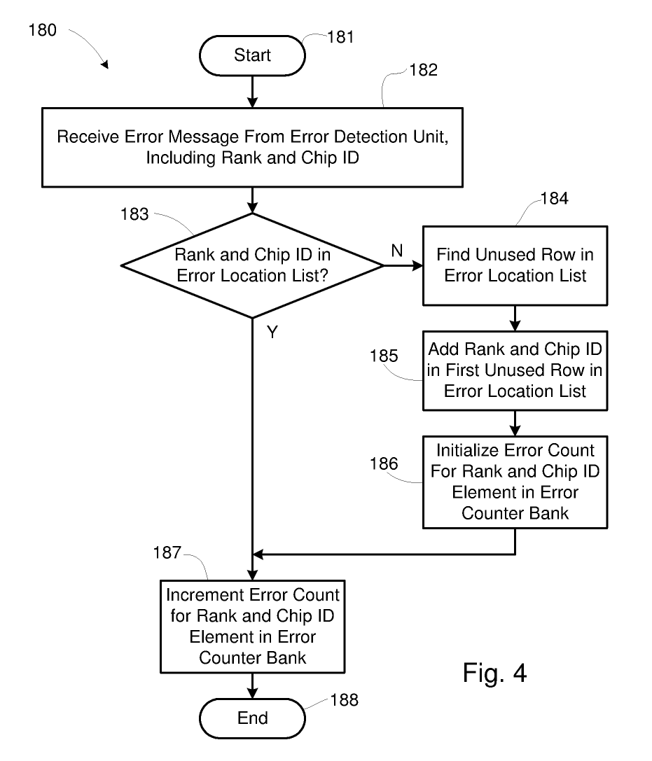

Error logging unit 104 comprises a compare 150 and an error location list 160 that further comprises a number of error rows; each error row is called an error list item 164. Each error list item 164 further comprising a valid column 161, a rank ID column 162 and a chip ID column 163. Rank ID is the identity of a particular memory rank 112; chip ID is the identity of a particular memory chip 110 in a rank. Error logging unit 104 further comprises error counter bank 170 coupled to compare 150 by increment signal 151. Operation of error logging 104 is best described by a flow chart shown in FIG. 4 that describes method 180. Method 180 in FIG. 4 will now be described with reference also to blocks in FIG. 3.

Method 180 begins at block 181. In block 182, compare 150 receives an error message from error detection unit 103, the error message comprising identification of the memory rank 112 and the memory chip 110 associated with the error detected by error detection unit 103.

Block 183 checks to see if the memory rank and memory chip identified are already in error location list 160. Rank ID is found in rank ID column 162; chip ID is found in chip ID column 163. Valid column 161 is a column in error location list 160 that has a “1” for each row in error location list 160 that has a rank ID and chip ID combination for which an error has been detected. If a particular row in error location list 160 is not associated with an error associated with a rank ID and chip ID combination, then there is a “0” in the valid column 161 for that row. If no error for any rank and chip combination has been detected by error detection unit 103 then there is a “0” in valid column 161 for each row in error location list 160. If an instant rank ID and chip ID combination identified as having an error, as reported by error detection unit 103, is found in a row of error location list 160, compare 150 activates increment signal 151 to increment the value of an error count in a corresponding row in error counter bank 170. Block 187 in method 180 in FIG. 4 shows incrementing an error count in error counter bank 170 corresponding to a particular rank ID and chip ID having an error, as identified by error detection unit 103. Incrementing may be implemented as incrementing by a negative number.

For example, in FIG. 3 a current value of the error count in the second row (column titles are shown for description only) of error counter bank 170 is 19. If error detection unit 103 detects an error in data 109 for rank 1, chip 1, error detection unit 103 transmits an error message containing information that an error occurred in data read from rank 1, chip 1. Compare 150 receives the error message and checks to see if a valid row (i.e., the bit in valid column 161 for that row is “1”) in error location list 160 contains an identifier for rank 1, chip 1. The second row (again, column titles are shown for description only) has a “1” in valid column 161; a “001” for rank ID, and a “0001” for chip ID and therefore has found a match with the instant error message. Compare 150 therefore activates increment signal 151 along with information specifying which row of error counter bank 170 to increment (row 2 in this example), causing the current value, 19, to be incremented to 20.

In an embodiment, compare 150 is configured to compare all rows in error location list 160 in parallel to speed finding a match in a valid row between the rank ID and chip ID in the error message and an error list item 164 in error location list 160. In an embodiment, error location list 160 is configured as a CAM (content addressable memory) to perform the task of finding a match in a valid row between the rank ID and chip ID in the error message with a valid row containing the same rank ID and chip ID. In an embodiment, compare 150 is configured to iterate through valid rows of error location list 160 to attempt to find a match between the rank ID and chip ID in the error message with a rank ID and chip ID in a row in error location list 160.

If block 183 does not find a match in a valid row between the rank ID and chip ID in the error message and a rank ID and chip ID in error location list 160, block 184 selects an unused row (i.e., the entry in that row of valid column 161 is “0”) in error location list 160. In an embodiment in which error location list 160 is sequentially searched, block 184 would advantageously choose the first unused row (valid column value=“0”) in error location list 160. In the case of a parallel search, such as in embodiments where error location list 160 is configured as a CAM, any unused row may be selected. Block 185 adds the rank ID and chip ID to the selected row in error location list 160, and the row is marked as valid (setting the valid column for that row to “1”). Block 186 initializes an error count value for a row in error counter bank 170 corresponding to the row selected in error location list 160 in block 184. Block 186 passes control to block 187, where the just-initialized error count value in error counter bank 170 is incremented. Block 188 ends method 180.

In an embodiment, any error detected by error detection unit 103 is transmitted to error logging unit 104, whether the error occurred during a scrubbing operation or during a functional read. A functional read is a read of data from memory 108 (FIG. 1) responsive to a read request issued by processor 102. Some computer systems comprise a plurality of nodes, wherein a processor in a first node may issue a read request to a memory in a second node, and this is also a functional read. Since functional reads are performed far more often than reads associated with a scrubbing operation, errors are typically found more quickly during functional reads than with a conventional error logging system in which only errors occurring during scrubbing operations are logged. Furthermore, since error counts are kept for each memory rank 112 and memory chip 110, scrubbing operations need not be completed on a first memory rank 112 before scrubbing can begin on a second memory rank 112.

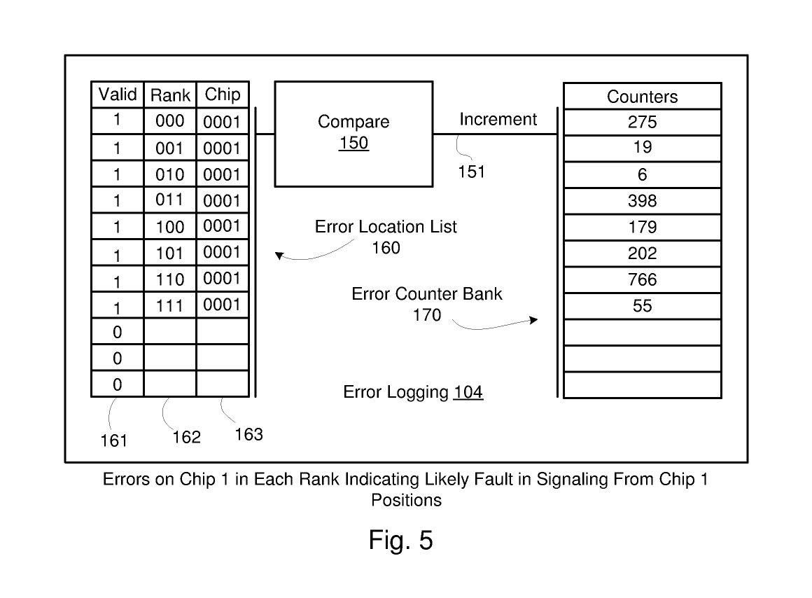

FIG. 5 illustrates how particular failures can be identified as a fault pattern quickly using data collected in error logging unit 104. Reliability of memory 108 (FIG. 1) can be increased if certain fault patterns are quickly determined and spare memory ranks 112 and/or spare memory chips 110 are used responsive to determination of the certain fault patterns.

For example, suppose that one or more signal conductors in a particular data 109 are faulty, such as shorted to ground, for example. In FIG. 5, error location list 160 indicates that the four bits connected to each memory chip 110₁ are found to have errors, no matter which memory rank 112 is accessed. Therefore, it is highly probable that one or more signal conductors in data₁ 109 are faulty, or a receiving circuit (not shown) in memory controller 106 is faulty. Many modern computers have spare memory chips 110 coupled to spare data₁ 109 conductors and, upon detection of a fault in a particular data 109, the spare data 109 and the spare memory chips 110 are used instead, allowing the computer system to reliably continue operation. It is possible, as noted above, that if a single signal conductor in a faulty data 109 is faulty, faulty data read may be corrected by an ECC implementation of error detector unit 103. However, a second error, either a hard error or a soft error will result in uncorrectable data being received by memory controller 106.

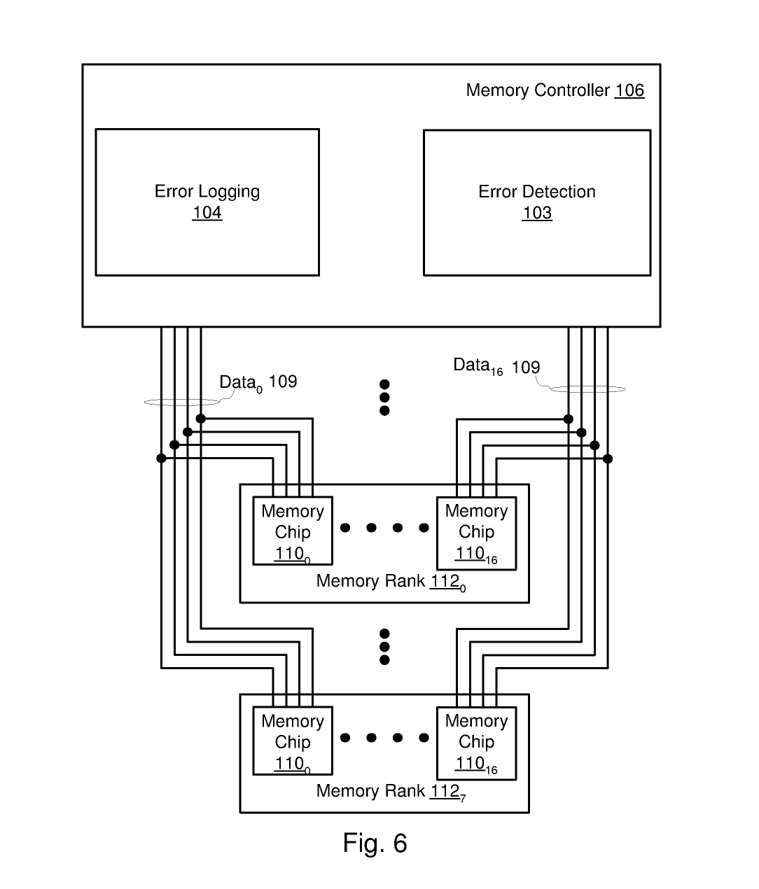

FIG. 6 shows memory controller 106 and memory ranks 112, similar to FIG. 2, but has seventeen memory chips 110 in each rank instead of sixteen memory chips in each rank as show in FIG. 2. The seventeenth memory chip, memory chip₁₆ 110 and the seventeenth data 109, data₁₆ 109, are the spare memory chips 110 and the spare data 109 described above. Reliability of memory 108 is improved by using the spare memory chips 110 and the spare data 109 instead of the memory chips 110 (memory chips 110₁ in the example) and data 109 (data 109 in the example) found to have a common fault.

Other particular failures can be identified as a fault pattern using data collected in error logging unit 104, and the above description is just one such particular failure. For example, using error location list 160 information, it is easy to detect if a particular rank has had errors in multiple chips. Having multiple chip errors in a single rank means that rank has a potential for uncorrectable errors under some conditions, depending upon implementation in a particular memory 108. Such condition can be found, for example, by sorting valid rows in error location list 160 first by rank ID and then by chip ID and checking for multiple errors within a single rank. Alternatively, a sophisticated program could discover a single rank having multiple chip errors by iterating through valid error list items 164 and keeping track of how many memory chips 110 in each memory rank 112 have experienced errors. A memory 108 may be configured with a spare memory rank 112. For example, in FIG. 2, memory ranks 112₀ to 110₆ may be non-spare ranks, with memory rank 112₇ being the spare memory rank. Memory controller 106, upon detection of a fault pattern wherein all chips 110 in a particular memory rank 112 are failing, reconfigures memory 108 to use the spare memory rank 112 instead of the failing memory rank 112, thereby improving reliability of memory 108.

Referring again to FIG. 5, it would be unlikely that the fault pattern seen (i.e., the same memory chip 110 in each consecutive memory rank 112 is seen to be faulty) would be so obvious when viewing error location list 160. For example, there may be other memory chips 110 from various memory ranks 112 in valid rows of error location list 160. While a sophisticated analysis of rank IDs and chip IDs in valid rows of error location list 160 can find such patterns, sorting by chip ID and rank ID eases the task of identifying patterns. Memory controller 106, in an embodiment, copies valid rows of error location list 160 to a working memory (not shown, but may be registers in memory controller 106 or in one or more memory ranks 112). Memory controller 106 then sorts the working memory first by chip ID and then by rank ID, which produces easy to detect fault patterns of errors by rank ID and chip ID as shown in FIG. 5. In an alternative embodiment rows in error location list 160 are sorted in place, that is, in error location list 160. In such an alternative embodiment, corresponding error counts in error counter bank 170 must be moved to maintain row relationship with the corresponding row in error location list 160.

Yet another fault pattern is an error count for a particular rank ID and chip ID combination that exceeds a value specified by a designer or administrator. For example, referring to FIG. 3, if the designer or administrator has specified that an error count for any particular row ID and chip ID combination is to exceed 397, rank 5 (binary 101), chip 2 (binary 0010) exceeds the prespecified value (having a current value of 398). Chip 2 in rank 5 is identified has having an excessive number of errors, and perhaps has a hard fail, or a soft error in a frequently read memory chip 110 and memory rank 112 combination. An occurrence of an additional error (hard or soft) in rank 5 may exceed error correction capability of error detection 103, which would likely result in computer system 100 having to be shut down. For continued reliable operation, in response, memory controller 106 will use a spare chip on rank 5 instead of chip 2. Reliable operation means that one newly occurring error can be corrected, rather than causing an uncorrectable error condition.

An error count in a particular row ID and chip ID combination that exceeds the prespecified value may occur if a soft error exists for that chip ID in that row ID, and frequent read accesses are made to that particular row ID and chip ID combination. In an embodiment, when a particular error count exceeds the prespecified value, memory controller 106 forces a scrub operation, comprising a number of scrubs sufficient to scrub the particular row ID and chip ID combination, which would correct the soft error. The error counter for that particular row ID and chip ID combination is reset; however, a flag is set in scrub column 165 (FIG. 8) in an embodiment of error location list 160 to indicate that that an attempt to scrub the soft error has been made. If the error count in that particular rank ID and chip ID combination again (i.e., the corresponding scrub column 165 bit is “1”) exceeds the prespecified value, a hard error is assumed, and memory controller 106 selects a spare memory chip 110 and/or a spare memory rank 112 to use instead of the particular row ID and chip ID combination. Memory controller 106 copies data stored in the particular row ID and chip ID combination to the spare row ID and chip ID, and then future accesses will be made to the spare memory rank 112 and/or memory chip 110.

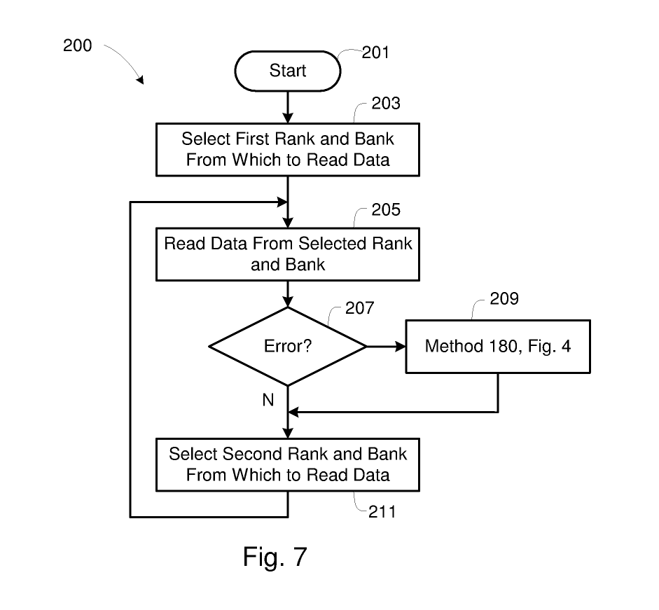

FIG. 7 shows a high level flow chart embodiment of the invention. Method 200 begins at block 201, and is applicable for a computer system as depicted in FIG. 1 and described above. In block 203, a first rank and bank in a memory is selected by a memory controller for a read. In block 205, data is read from the first rank and bank selected. An error detection unit examines the data read from the first rank and bank. If an error is detected in the data read, block 207 passes control to block 209, which performs the steps of method 180, as shown in FIG. 4 and described in reference to FIG. 4. In block 211, a second bank, different from the first bank, is selected for a read, with control passing to block 205 which reads data from the selected second rank and bank. Method 180, when an error is detected, maintains error items for each rank ID and bank ID combination for which an error is detected, and maintains a count, for each error list item, of how many times an error for that rank ID and bank ID combination occurs. Typically, error counts are all reset, along with all columns in the error location list (error location list 160, FIG. 3, FIG. 8), after elapse of an interval specified by a designer or system administrator. For example, error counts and all columns in the error location list may be reset every twenty four hours. This resetting is done in step 201 of method 200, where method 200 is executed at the beginning of the interval specified by the designer or system administrator.

What is claimed is:

1. A computer system comprising:
a processor;
a memory further comprising a plurality of memory ranks coupled to the memory controller, each memory rank further comprising a plurality of memory chips;
an error detection unit configured to detect an error in data read from the memory and identifying a rank ID and a chip ID associated with the error; and
a memory controller coupled to the processor and to the memory, the memory controller configured to concurrently maintain error information for multiple memory ranks in the plurality of memory ranks.

2. The computer system of claim 1, the memory controller further comprising:
an error location list further comprising an error list item for each rank ID and chip ID combination for which an error has been detected by the error detection unit; and
an error counter bank configured to maintain an error count indicating how many times an error has been detected by the error detection unit for each rank ID and chip ID combination in the error location list.

3. The computer system of claim 2 wherein the error location list is configured as a content addressable memory.

4. The computer system of claim 2, the memory controller configured to examine the error location list to detect a fault pattern and to use a spare memory chip or a spare memory rank responsive to the fault pattern.

5. The computer system of claim 4, the fault pattern comprising an error in a particular chip for each memory rank in the plurality of memory ranks, the memory controller configured to use a spare memory chip in the plurality of memory ranks instead of the particular memory chip.

6. The computer system of claim 4, the fault pattern comprising an error in every memory chip in a particular memory rank, the memory controller configured to use a spare memory rank instead of the particular memory rank.

7. The computer system of claim 4, the fault pattern comprising a particular memory rank and memory chip combination having more than a specified number of errors, the memory controller configured to force a scrub of the particular memory rank, reset the error counter for the particular memory rank and memory chip combination, and set a flag that a scrub was performed on the particular memory rank; if, subsequently, the particular memory rank and memory chip combination again has more than the specified number of errors, the memory controller configured to then use a spare memory chip on the same memory rank, or to use a spare memory rank instead of the particular memory rank.

8. The computer system of claim 1 wherein the error detection unit is an error checking and correction unit.

9. The computer system of claim 1, wherein the data read from the memory is read during a scrub read.

10. The computer system of claim 1, wherein the data read from the memory is read during a functional read.

11. A method performed by a computer system having a memory controller coupled to a memory further comprising a plurality of memory ranks, each memory rank further comprising a plurality of memory chips, including one or more spare memory chips, the method comprising:
concurrently maintaining an error count for each memory rank and memory chip combination in the memory that has encountered an error;
analyzing the concurrently maintained error count for each memory rank and memory chip combination that has encountered an error to determine a fault pattern; and
using the fault pattern to improve reliability of the memory by using the one or more spare memory chips.

12. The method of claim 11, wherein the fault pattern comprises an error for a corresponding memory chip in each memory rank in the plurality of memory ranks.

13. The method of claim 11, wherein the fault pattern comprises an error for every memory chip in a particular memory rank in the plurality of memory ranks.

14. The method of claim 11, further comprising:
detecting an error in data read from the memory;
determining a rank ID and a chip ID combination associated with the error;
associating an error counter with the rank ID and chip ID combination associated with the error; and
incrementing the error counter associated with the rank ID and chip ID combination.

15. The method of claim 14, further comprising:
storing the rank ID and chip ID combination associated with the error in a content addressable memory (CAM).

16. The method of claim 14, associating the error counter with the rank ID and chip ID combination associated with the error comprises iterating through an error location list to match the rank ID and chip ID combination associated with the error with a rank ID and chip ID combination stored in the error location list.

17. The method of claim 14, associating the error counter with the rank ID and chip ID combination associated with the error comprises a parallel compare of the rank ID and the chip ID combination associated with the error with one or more rank ID and chip ID combinations stored in the error location list.

18. The method of claim 11, further comprising resetting of the error count for each rank ID and chip ID combination at specified intervals.

19. The method of claim 11, further comprising:
if the error count for a particular rank ID and chip ID combination exceeds a specified value, then
forcing a scrub of a particular memory rank identified by the particular rank ID;
resetting the error count for the particular rank ID and chip ID; and
setting a flag that the particular memory rank was scrubbed; and
if the error count for the particular rank ID and chip ID combination exceeds the specified value and the flag for the particular rank is set, then using a spare memory chip or a spare memory rank to replace the particular memory rank or a particular memory chip identified by the particular rank ID and chip ID combination.

20. The method of claim 19, further comprising copying data from the particular memory rank or particular memory chip identified by the particular chip ID and rank ID combination to the spare memory chip or spare memory rank.
